(19) United States
(12) Patent Application Publication
(10) Pub. No.: US 2007/0059923 A1
(43) Pub. Date: Mar. 15, 2007

(54) Methods of fabricating damascene interconnection line in semiconductor devices and semiconductor devices fabricated using such methods

(75) Inventors: Hyo-jong Lee, Seoul (KR); Ui-hyoung Lee, Seoul (KR); Hong-jae Shin, Seoul (KR); Nae-in Lee, Seoul (KR); Soo-geun Lee, Suwon-si (KR)

Correspondence Address: LEE & MORSE, P.C., 3141 FAIRVIEW PARK DRIVE, SUITE 500, FALLS CHURCH, VA, 22042, US

(73) Assignee: Samsung Electronics Co., Ltd.

(21) Appl. No.: 11/445,458

(22) Filed: Jun. 2, 2006

(30) Foreign Application Priority Data
Jun. 4, 2005 (KR) 10-2005-0048100

(51) Int. Cl. H01L 21/4763

(52) U.S. Cl. 438/637

(57) ABSTRACT

Methods of fabricating an interconnection line in a semiconductor device and a semiconductor device including such an interconnection line. The method involves forming a lower interconnection line on a semiconductor substrate, forming a mold pattern that defines an opening through which the lower interconnection line is exposed, filling the opening with a conductive material to form a via, removing the mold pattern to make the via remain on the lower interconnection line, forming an interlevel dielectric (ILD) layer that covers the lower interconnection line and the via, patterning the ILD layer, exposing the via, forming a trench that defines a region in which an interconnection line is to be formed, and filling the trench to fabricate a damascene interconnection line connected to the via.

### BACKGROUND OF THE INVENTION

1. Field of the Invention

The invention relates to methods of fabricating an interconnection line in a semiconductor device and semiconductor devices fabricated using such methods of fabricating an interconnection line in a semiconductor device. More particularly, the invention relates to methods of fabricating a damascene interconnection line in a semiconductor device, and semiconductor devices fabricated by such methods.

2. Description of the Related Art

As the efficiency and integration of microelectronic devices are increasing, more multi-layered interconnections are being used in semiconductor devices. To obtain reliable devices, which include multi-layered interconnections, the interconnection layers are generally formed as planar layers, which may be interconnected via dual damascene interconnections.

FIGS. 1 through 3 are cross-sectional views of a known method of fabricating a damascene interconnection line in a semiconductor device.

Referring to FIG. 1, an etch stopper 30 is formed on a semiconductor substrate 10 on which a lower interconnection line 20 is formed. An interlevel dielectric (ILD) layer 40 is formed on the etch stopper 30. Next, the ILD layer 40 is patterned to form a first opening 51 through which a top surface of the etch stopper 30 is exposed. The first opening 51 is then filled with a filler 60.

Referring to FIG. 2, a photoresist pattern 70, which defines a second opening 52 is formed. The second opening 52 has a width, e.g., distance between opposite walls of the second opening 52, that is larger than a width of the first opening 51 and which is an interconnection line region through which a portion of the ILD layer 40 is exposed is formed. The position of the second opening 52 corresponds to the position of the first opening 51 such that the first opening 51 overlaps with the second opening 52. The ILD layer 40 and the filler 60 are dry etched using the photoresist pattern 70 as an etching mask. As a result of the etching process, an interconnection line region 52′ corresponding to the second opening 52 is formed in the ILD layer 40.

Referring to FIG. 3, the photoresist pattern 70 and the filler 60 that remains in the first opening 51 are removed so that s top surface of the etch stopper 30 is exposed. A portion of the etch stopper 30, which is exposed through the first opening 51, is removed so that a via region 51′ is formed between the lower interconnection line 20 and the interconnection line region 52′. A barrier conductive layer 80 is then formed in the via region 51′ and the interconnection line region 52′. The via region 51′ and the interconnection line region 52″ are then filled with a conductive material and planarized to respectively form a via 91 and a dual damascene interconnection line 92.

In such known conventional dual damascene interconnection lines, a filler should be used to prevent an etch gas, which may be used when the first opening 51 is formed, from damaging the ILD layer 40 and/or the photoresist pattern 70 when the second opening 52 is formed. Thus, a process of fabricating such dual damascene interconnection lines is complicated.

Also, an electroplating method may be used to fill a via, e.g., via 51, with a conductive material. In such cases, a plating material may grow in both a bottom portion and a sidewall portion of the via. The speed of growth of the plating material in the sidewall of the via is faster than the bottom portion of the via. The plating material growing in the sidewall(s) of the via 51, e.g., opposing sidewalls at the entrance of the via, may meet and close the entrance to the via 51 before the via is filled with a conductive material. When the via entrance is closed before the via 51 is filled with the conductive material, the lower interconnection line 20 and the damascene interconnection line 92 may not be electrically connected and/or may not be sufficiently connected. Thus, the electrical characteristics of the device may be degraded. As design rules of semiconductor devices are decreasing further and further, e.g., 90 nm to 65 nm and 45 nm, etc., this phenomenon is likely to occur more frequently.

In addition, in known dual damascene interconnection lines, a same material is used to form a via and an upper damascene interconnection line. When a damascene interconnection line is to be formed of a low resistance conductive material and the via 51 is to be formed of a material, which is highly resistant to stress induced voiding (SIV), and/or when electromigration (EM) properties of the materials are different, satisfying all of the requirements is difficult and/or impossible.

### SUMMARY OF THE INVENTION

The invention is therefore directed to methods of fabricating damascene interconnection lines and semiconductor devices fabricated by such methods, which substantially overcome one or more of the problems due to the limitations and disadvantages of the related art.

It is therefore a feature of an embodiment of the present invention to provide a simple method of fabricating a reliable damascene interconnection line in a semiconductor device and to semiconductor devices including such damascene interconnection lines.

At least one of the above and other features and advantages of the present invention may be realized by providing a method of fabricating a damascene interconnection line in a semiconductor device, the method involving forming a lower interconnection line on a semiconductor substrate, forming a mold pattern that defines an opening through which the lower interconnection line is exposed, filling the opening with a conductive material to form a via, removing the mold pattern while maintaining the via on the lower interconnection line, forming an interlevel dielectric (ILD) layer that covers the lower interconnection line and the via, patterning the ILD layer, exposing the via, and forming a trench that defines a region in which an interconnection line is to be formed, and filling the trench to fabricate a damascene interconnection line connected to the via.

Forming the mold pattern may include forming a photoresist layer on the semiconductor substrate in which the lower interconnection line is formed, and exposing and developing the photoresist layer. Removing the mold pattern may involve removing the mold patter using a stripper including at least one amine-based material. The amine-based material may include at least one of N-methylethanolamine, mono ethanolamine, hydroxylamine and diglycolamine.

Forming the mold pattern may involve forming a mold layer on the semiconductor substrate in which the lower interconnection line is formed, forming a photoresist pattern, which defines the opening, on the mold layer, etching the mold layer using the photoresist pattern as an etching mask, and removing the photoresist pattern.

Forming the via may involve selectively filling the opening with the conductive material. Forming the via may involve performing electroless plating or chemical vapor deposition (CVD). The conductive material may include at least one of Cu, Ni, Sn, W and alloys thereof. The conductive material may be different from a material used to fabricate the damascene interconnection line.

The method of fabricating a damascene structure may involve forming a diffusion-prevention and etch stop layer before the forming of the ILD layer, wherein forming of ILD layer includes interposing the diffusion-prevention and etch stop layer to cover the lower interconnection line and the via, and exposing the via includes etching the ILD layer to the diffusion-prevention and etch stop layer that covers the via and removing the diffusion-prevention and etch stop layer that covers the via.

The diffusion-prevention and etch stop layer may be formed of at least one of SiC, SiN and SiCN. Forming the diffusion-prevention and etch stop layer comprises selectively forming the diffusion-prevention and etch stop layer in a region in which the lower interconnection line and the remaining via are formed. The diffusion-prevention and etch stop layer may be formed of CoWP. Forming the diffusion-prevention and etch stop layer may involve electroless plating. Forming of ILD layer may include forming the ILD layer using spin coating. Forming the ILD layer may involve conformally depositing an interlevel dielectric (ILD) material, and planarizing a top surface of the deposited ILD material.

At least one of the above and other features and advantages of the present invention may be separately realized by providing a semiconductor device including a lower interconnection line, a via formed of conductive material, the via being electrically connected to the lower interconnection line, a diffusion-prevention and etch stop layer formed on sidewalls of the via, and a damascene interconnection line electrically connected to the via.

A barrier metal layer may be formed at a boundary between the damascene interconnection line and the via. The barrier metal layer may be formed of at least one of Ta, TaN, TiN, WN, TaC, WC, TiSiN and TaSiN. The conductive material may include at least one of Cu, Ni, Sn, W and alloys thereof. The conductive material is different from a material forming the damascene interconnection line. The diffusion-prevention and etch stop layer is formed of at least one of SiC, SiN, and SiCN. The diffusion-prevention and etch stop layer is formed on the sidewalls of the via that extend away from the lower interconnection line and on a top surface of the lower interconnection line. The diffusion-prevention and etch stop layer is formed of CoWP.

The above stated objects as well as other objects, features and advantages, of the invention will become clear to those skilled in the art upon review of the following description.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIGS. 1 through 3 illustrate cross-sectional views of a stages of a method of fabricating a damascene interconnection lines in a semiconductor device;

FIGS. 4 through 6 and 8 through 11 illustrate cross-sectional views of stages of a method of fabricating an interconnection line in a semiconductor device, according to one or more aspects of the invention;

FIG. 7 is a photograph of a result of a copper electroless plating process performed on a semiconductor substrate to form a via;

FIGS. 12 and 13 illustrate cross-sectional views of stages of a method of fabricating an interconnection line in a semiconductor device, according to one or more aspects of the invention; and

FIGS. 14 through 16 illustrate cross-sectional views of stages of a method of fabricating an interconnection line in a semiconductor device, according to one or more aspects of the invention.

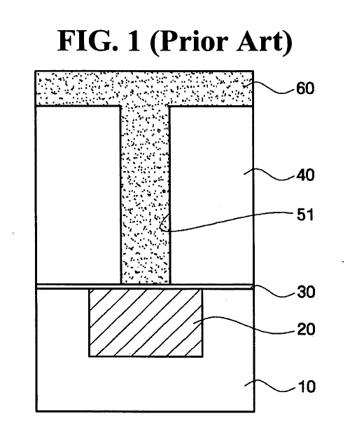

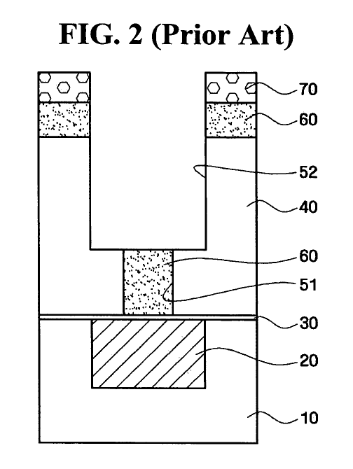

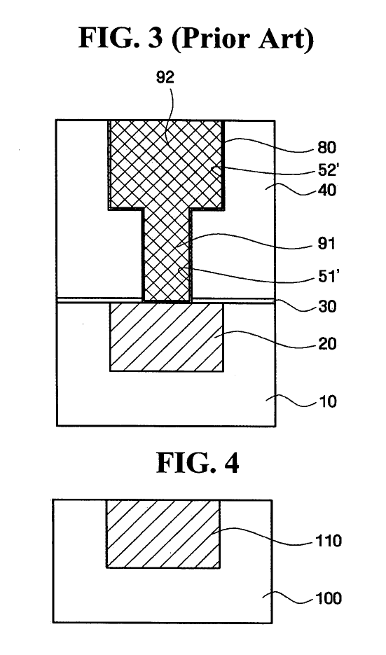

### DETAILED DESCRIPTION OF THE INVENTION

Korean Patent Application No. 10-2005-0048100, filed on Jun. 4, 2005, in the Korean Intellectual Property Office, and entitled: “Method of Fabricating Damascene Interconnection Line in Semiconductor Device and Semiconductor Device Fabricated by the Same,” is incorporated by reference herein in its entirety.

The present invention will now be described more fully hereinafter with reference to the accompanying drawings, in which exemplary embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the figures, the dimensions of layers and regions are exaggerated for clarity of illustration. It will also be understood that when a layer is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

Referring to FIGS. 4 through 11, an exemplary method of fabricating dual damascene interconnections according to one or more aspects of the invention will be described below. FIGS. 4 through 11 illustrate cross-sectional views of stages in a method of fabricating an interconnection line in a semiconductor device, according to one or more aspects of the invention.

As shown in FIG. 4, a lower interconnection line 110 may be formed on a semiconductor substrate 100. Various active and/or passive element(s) (not shown) may be included on the semiconductor substrate 100. The lower interconnection line may be formed, e.g., of low resistance materials, e.g., copper. Various materials, e.g., copper, copper alloy, aluminum and/or aluminum alloy, may be used to form the lower interconnection line 110. The surface of the lower interconnection line 110 may be planarized.

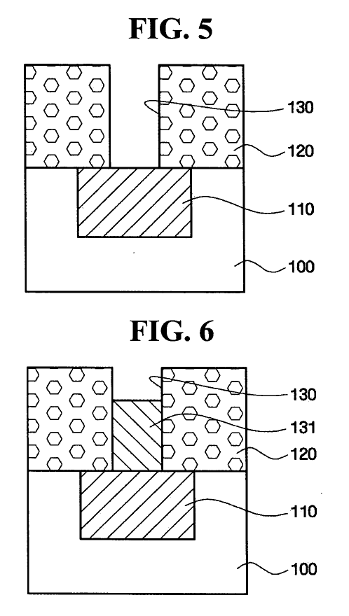

As shown in FIG. 5, a mold pattern 120, which may define an opening 130 may be formed on the semiconductor substrate 100 on which the lower interconnection line 110 is formed. The mold pattern 120 may be formed, e.g., of a photoresist layer. In embodiments of the invention, the opening 130 may at least partially or completely overlap the lower interconnection line 110 and the a portion of the lower interconnection line 110 may be exposed through the opening 130.

An exemplary method for forming the mold pattern 120 from, e.g., a photoresist layer, will be described below. Photoresist may be uniformly coated on the semiconductor substrate 100, on which the lower interconnection line 110 is formed, to form a photoresist layer (not shown). The photoresist layer may be uniformly coated using, e.g., a spin method.

The resulting structure may then be soft baked to evaporate, e.g., any solvent and/or water, from the previous steps. The soft baking may also help solidify the coated photoresist layer. The soft bake may be performed using, e.g., a thermal plate at a temperature of about 90° to about 120° for about, e.g., 60 seconds to about 150 seconds. A patterned mask may be formed and/or arranged on the photoresist and the patterned mask may be irradiated with light. The patterned mask may define the opening 130 and the light may be irradiated using, e.g., exposure equipment, e.g., a stepper. After the photoresist layer is soft-baked and irradiated with light, the photoresist layer may be soaked in a developing agent, e.g., tetramethyl ammonium hydroxide, and one of the exposed or non-exposed portions of the photoresist layer may be removed. In embodiments of the invention, only portions of the photoresist layer exposed to the light will dissolve in the developing agent such that the mold pattern 120 corresponding to a shape of the patterned mask used to irradiate the photoresist layer may remain. The resulting structure may correspond to, e.g., the mold pattern 120 formed of a photoresist layer that defines the opening 130 illustrated in FIG. 5.

The semiconductor substrate 100 may then be hard baked at about 100° to about 130° for, e.g., about 10 seconds to about 300 seconds. Such hard baking may further solidify the mold pattern 120 and may increase an adhesive force to strengthen the resistance of the mold pattern to subsequent physical and/or chemical stimuli, to which the mold pattern 120 may be subjected.

Thickness of the mold pattern 120 may correspond to a minimum thickness that enables, e.g., formation of a via in the opening 130 that may be defined by the mold pattern 120. The thickness of the mold pattern 120 may correspond to a height of the mold pattern 120 relative to the semiconductor substrate 100. The thickness of the mold pattern 120 may be, e.g., about 2000 Å to about 20000 Å. In embodiments of the invention, the thickness of the mold pattern 120 may be, e.g., about 4000 Å to about 10000 Å. However, the thickness of the mold pattern 120 is not limited to such ranges and the mold pattern 120 may have a thickness outside of the above-mentioned ranges depending on characteristics of the device and/or materials used, e.g., according to the type of a semiconductor device and the size of a via.

As shown in FIG. 6, the opening 130 through which the lower interconnection line 110 is exposed may be filled with a conductive material to form a via 131. Any conductive material, e.g., Cu, Ni, Sn, W, or alloy(s) thereof may be used to form the via 131. The lower interconnection line 110 and an upper damascene interconnection line 161 (shown in FIG. 11) may be electrically connected using the conductive material.

The conductive material may be selectively filled in the opening 130 defined by the mold pattern 120. In embodiments of the invention, the conductive material is only selectively deposited such that the conductive material is only deposited at intended locations, e.g, in the opening 130. In such embodiments, if the conductive material is deposited on portions of the mold pattern 120, which do not correspond, e.g., to the opening 130, it may be difficult to remove the mold pattern 120 during a subsequent process and/or the filled conductive material may unintentionally or undesirably contact other layers of the semiconductor device. By selectively filling the opening 130, the via 131 may be formed in the opening 130 defined by the mold pattern 120.

The conductive material may be filled from a bottom portion of the opening 130, e.g, the lower interconnection line 110 exposed by the opening 130 and/or the conductive material may be grown along an upward direction in the opening 130 to reduce and/or prevent pinch off from occurring at, e.g., an upper portion of the opening 130. Pinch off may occur, e.g., if the conductive material is filled from the bottom portion of the opening 130 and simultaneously grown from sidewalls of the opening 130 and the conductive material growing from the sidewalls forms faster and closes off an entrance to the opening 130 before the opening 130 is filled with the conductive material. To prevent and/or reduce the occurrence of such pinch off, in embodiments of the invention, the conductive material may be grown only in the upward direction from the lower interconnection line 110.

Electroless plating is an example of a method that may be used to fill the conductive material in the upward direction from the bottom portion of the opening 130, e.g., the lower interconnection line 110. Electroless plating is a chemical reduction process in which metal ions in a metal-salt aqueous solution are self catalyst reduced using the effect of a reduction and the metal ions are deposited or plated on the surface of an object without the use of external electrical energy. Electroless plating may be used to selectively stack ions on the lower interconnection line 110 and then, additional ions may be stacked on the stacked metal ions such that the conductive material can be grown in the upward direction from the lower interconnection line 110.

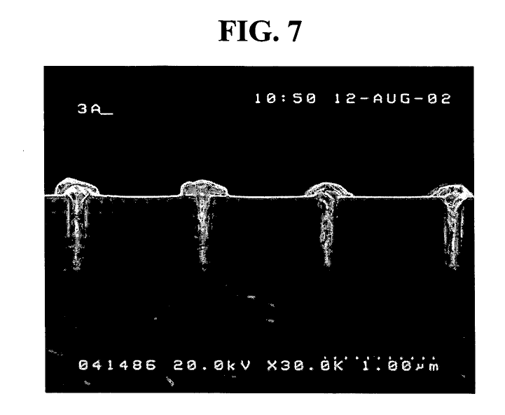

FIG. 7 shows the result of copper plating using electroless plating. FIG. 7 is a photo of the result of copper plating in which electroless plating is performed on a semiconductor substrate in which a via is formed, for a sufficient time. Referring to FIG. 7, copper is plated in an opening and grown in the upward direction using electroless plating and plating and deposition of copper is not performed on a mold pattern.

Referring back to FIG. 6, in embodiments of the invention, a chemical vapor deposition (CVD) may be used to fill the conductive material in the upward direction from the lower interconnection line 110. CVD is a technology of depositing a thin film by injecting a reactive gas into a vacuum chamber, applying proper active and thermal energy and inducing a chemical reaction. For example, tungsten (W) can be selectively deposited using CVD and tungsten (W) can be selectively grown on the lower interconnection line 110.

In embodiments of the invention, a via 131 may be formed before a damascene interconnection line is 161 (shown in FIG. 11) is formed on the via 131. That is, in embodiments the invention, the process of forming the via 131 and the process of fabricating the damascene interconnection line 161 may be separated from each other. By separating the process of forming the damascene interconnection line 161 from the process of forming the via 131, it is possible to easily form the via 131 and the damascene interconnection line 161 with different conductive materials. Thus, embodiments of the invention enable the damascene interconnection line 161 to be formed of a low resistance material, e.g., copper or copper alloy, and the via 131 to be formed of a material, e.g., nickel, having a stronger resistance to stress induced voiding and/or electromigration than the low resistance material used in the damascene interconnection line 161 for low resistance.

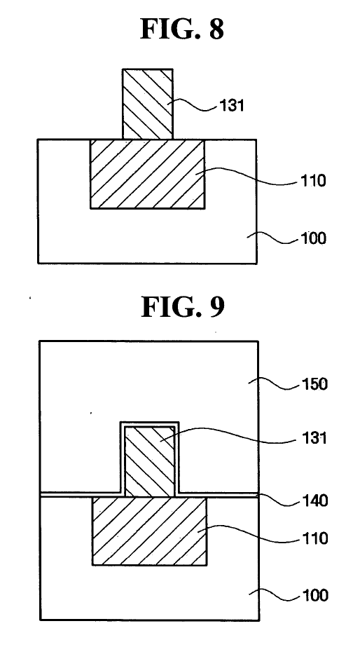

As shown in FIG. 8, after the via 131 is formed on the lower interconnection line 110 of the semiconductor substrate 100, the mold pattern 120 (shown in FIG. 6) may be removed.

Various processes may be used to remove the mold pattern 120. For example, in embodiments of the invention in which the mold pattern 120 was formed from a photoresist material, as discussed above, a general ashing and a photoresist strip process may be performed to remove the mold pattern 120. In embodiments of the invention in which sidewalls of the lower interconnection line 110 and sidewalls of the via 131 are exposed when the mold pattern 120 is removed, the via 131 or the lower interconnection line 110 may be damaged during the mold pattern 120 removal process. Thus, depending on the materials used for forming the mold pattern 120, a wet removal process, e.g., chemical stripper, may be preferable and/or necessary over a physical removal process, e.g., ashing, to remove the mold pattern 120.

In the exemplary embodiment described above in which the mold pattern 120 is formed from a photoresist layer, any agent that can selectively remove the mold 120, e.g., photoresist, without damaging the via 131 and/or the lower interconnection line 110 may be used as a mold remover in a wet removal process. A stripper including, e.g., at least one amine-based material may be used as the photoresist remover. The amine-based material may include, e.g., N-methylethanolamine, mono ethanolamine, hydroxylamine and/or diglycolamine, etc. The stripper may include N-dimethylacetamine, catechol, NH₄OH, CH₃COOH and H₂O.

Materials that may be included in the stripper used in a wet removal process for removing the photoresist layer may be combined according to the type and thickness of the photoresist to be removed and the type of material(s) used to form the via or the lower interconnection line.

As shown in FIG. 8, when the mold pattern 120 formed of the photoresist layer is selectively removed, the via 131 may remain on the lower interconnection line 110.

Referring to FIG. 9, in embodiments of the invention, a diffusion-prevention and etch stop layer 140 and/or an ILD layer 150 may be formed on the semiconductor substrate 100. The diffusion-prevention and etch stop layer 140 may cover the lower interconnection line 110 and the via 131. In embodiments of the invention including the diffusion-prevention and etch stop layer 140, the ILD layer 150 may cover, e.g., the diffusion prevention layer 140. In embodiments of the invention that do not include the diffusion-prevention and etch stop layer 140, the ILD layer may cover, e.g. the lower interconnection line 110 and the via 130.

The diffusion-prevention and etch stop layer 140 may be formed to reduce and/or prevent diffusion of the material used to form the lower interconnection line 110, e.g., copper and to reduce and/or prevent damage to the conductive material used to form the via 131 during, e.g., a dry etching process. Damage to the conductive material used to form the via 131 may impact the electrical characteristics of the conductive material. A dry etching process may be performed, e.g., to form a trench 160 (shown in FIG. 9). The diffusion-prevention and etch stop layer 140 may have an etch selectivity with respect to the ILD layer 150 and may be formed of a material having a dielectric constant of about 4 to about 5, e.g., SiC, SiN and SiCN. A thickness of the diffusion-prevention and etch stop layer 140 may be as minimum as possible in consideration of the effect on the dielectric constant of the ILD layer 150. The thickness of the diffusion prevention and etch stop layer 140 may correspond to a minimum thickness that is capable of performing a diffusion prevention and etch stop function.

In embodiments of the invention in which diffusion of the materials used to form the lower interconnection line 110 and the via 131 is not problematic or likely to occur, e.g., when the lower interconnection line 110 is formed of tungsten (W), diffusion into the ILD layer 150 does not occur, and the process of forming the diffusion-prevention and etch stop layer 140 can be omitted. In such cases, even when an etch stopper is not provided, a dry etching process for forming, e.g., a trench 160 (shown in FIG. 9), may be performed using, e.g., a time-control etch stop process, to reduce and/or prevent damage to the via 131.

As discussed above, in embodiments of the invention including the ILD layer 150, the ILD layer 150 may be formed on the diffusion-prevention and etch stopper 140. When the process of forming the diffusion-prevention and the etch stop layer 140 is omitted, the ILD layer 150 may be formed on the via 131 and the lower interconnection line 110. The ILD layer 150 may be formed of a material, e.g., having a high thermal stability and a low dielectric constant. To prevent and/or reduce RC signal delay between the lower interconnection line 110 and a damascene interconnection line to be formed and to suppress interference and increased power consumption, the ILD layer 150 may be formed of a material having a low dielectric constant. The ILD layer 150 may have a thickness sufficient to form the via 131 and the trench 160 (shown in FIG. 9). The ILD layer 150 may be formed of organic polymer or an inorganic material having a low dielectric constant (low-k).

The organic polymer may comprise, e.g., a low-k organic polymer, e.g., polyallylether-group resin, ring-shaped fluoride resin, siloxane copolymer, polyallylether-group fluoride resin, polypentafluorostylene, polytetrafluorostylene-group resin, polyimide fluoride resin, polynaphthalene fluoride resin and/or polycide resin, etc.

The inorganic material may comprise, e.g., an undoped silicate glass (USG) layer, a tetraethylorthosilicate (TEOS) layer, a fluorine-doped silicate glass (FSG) layer, an organo silicate glass (OSG) layer, a SiOC(SiOC:H) layer and/or a hydrogensilsesquioxane (HSQ) layer, etc.

A method of forming the ILD layer 150 may be one selected from a group consisting of plasma enhanced chemical vapor deposition (PECVD), high density plasma chemical vapor deposition (HDCVD), atmospheric pressure chemical vapor deposition (APCVD) and spin coating, etc.

In embodiments of the invention, the top surface of the ILD layer 150 may be planarized using, e.g., a spin coating method. When the ILD layer 150 is formed using, e.g., CVD, when an ILD material is deposited, the ILD layer 150 will be conformally formed with a step difference corresponding to a shape of the via 131 and the resulting ILD layer 150 will protrude from the semiconductor substrate 100 with a shape that corresponds to the shape of the via 131. Thus, a process of planarizing the top surface of the deposited ILD material using, e.g., an etchback or a CMP process, may be needed.

In embodiments of the invention, the ILD layer 150 may be formed to a thickness of about 3000 Å to about 20000 Å. In embodiments of the invention, the ILD layer 150 may have a thickness of about 6000 Å to about 7000 Å. The thickness of the ILD layer 150 may be outside of the above-mentioned range.

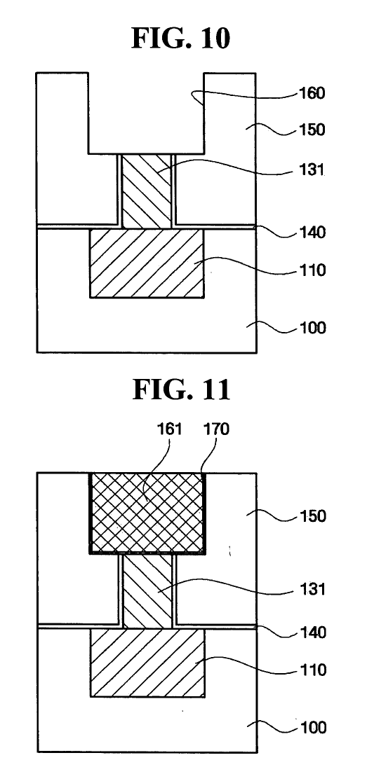

As shown in FIG. 10, the ILD layer 150 may be patterned and the via 131 may be exposed to form the trench 160, which may define a region in which a damascene interconnection line 161 is to be formed. To pattern the ILD layer 150, a photoresist layer (not shown) may be coated on the ILD layer 150 and the photoresist layer may be exposed using a mask (not shown). The mask may define the trench 160 in which an interconnection line is to be formed, and by developing the photoresist layer using the mask, the photoresist pattern that defines the trench 160 may be formed. The ILD layer 150 may later be etched using the photoresist pattern (not shown) as an etching mask. Etching of the ILD layer may expose portions of the diffusion-prevention and etch stop layer 140, as show in FIG. 10.

The trench 160 may be etched using, e.g., a dry etching process. In such cases, an etching gas that may be employed for dry etching may be, e.g., a gas containing O₂ or a gas containing N₂ or H₂. In embodiments of the invention, a mixture of a main etching gas, e.g., CₓF_{y} or CₓH_{y}F_{z} and an inert gas, e.g., Ar or a mixture obtained by adding at least one gas selected from O₂, N₂, and COₓ thereto may be used as the etching gas.

The diffusion-prevention and etch stop layer 140 may have an etch selectivity with respect to the ILD layer 150. An etching process may be performed in consideration of the thickness and etching selectivity of the ILD layer 150 and the diffusion-prevention and etch stop layer 140. To prevent damage to the via 131, the etching process may not remove all of the diffusion-prevention and etch stop layer 140. Thus, the etching process may not expose the via 131 and only a portion of the diffusion-prevention and etch stop layer 140 is removed using the above-described etching of the trench 160.

Next, the remaining portion of the diffusion-prevention and etch stop layer 140 may be removed, thereby exposing the upper portion of the via 131. Depending on the material used to form the diffusion prevention and etch stop layer 140, a gas used in an etchback process may be determined. For example, when the diffusion-prevention and etch stop layer 140 is formed of SiN, gases such as CF₄, CHF₃, and O₂ may be properly mixed. In embodiments of the invention, other gases may result.

In embodiments of the invention in which the diffusion-prevention and etch stop layer 140 is omitted, during etching of the ILD layer 150, the via 131 may not be exposed or may be etched too much. To reduce and/or prevent this problem, an etching time and/or an etching condition may be controlled and/or adjusted. To prevent and/or reduce damage to the via 131 while ensuring exposure of the via 131, in such cases, an etching process having a slow or moderate etching rate may be performed and/or the same etching condition(s) may be maintained throughout the etching process.

As shown in FIG. 11, a barrier metal layer 170 may be formed in the trench 160. The barrier metal layer 170 may be formed of at least one material selected from a group of Ta, TaN, WN, TaC, TiSiN and TaSiN. The barrier metal layer may be formed using, e.g., a physical vapor deposition (PVD) technique, a chemical vapor deposition (CVD) technique and an atomic layer deposition (ALD) technique. In embodiments of the invention in which copper (Cu) is used as a conductive material, the barrier metal layer 170 may be used to prevent degradation of insulating characteristics of the ILD layer 150 that may be caused by diffusion of Cu. In embodiments of the invention, depending, e.g., on the type of conductive material to be used to form the damascene interconnection line 161, the barrier metal layer 170 may not be formed.

To form the damascene interconnection line 161, the conductive material may be filled in the trench 160. The conductive material may then be planarized using, e.g., CMP, to form the damascene interconnection line 161. The conductive material may be, e.g., aluminum (Al), aluminum alloy (Al-alloy), copper (Cu), gold (Au), silver (Ag), tungsten (W) and molybdenum (Mo), etc. The conductive material may be formed using, e.g., a reflow technique for a layer formed by sputtering the conductive material, a chemical vapor deposition (CVD) technique and an electroplating technique, etc. In cases where an electroplating technique is used, a seed layer is required so that current may flow during electrolyzing.

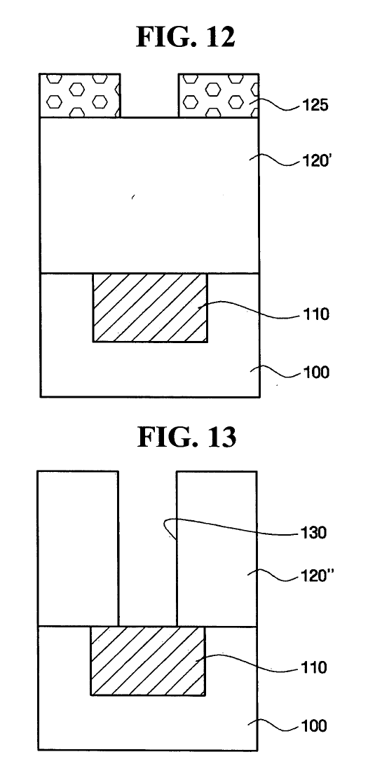

A method of fabricating a damascene interconnection line in a semiconductor device according to another embodiment of the invention will now be described with reference to FIGS. 12 and 13. The method illustrated in FIGS. 12 and 13 relates to a method of forming a via by forming a mold pattern as an insulating layer. Only differences between the exemplary embodiment illustrated in FIGS. 12 and 13 and the exemplary embodiment illustrated in FIGS. 4-6 and 8-11 will be described below.

In the exemplary embodiment shown in FIG. 12, a lower interconnection line 110 may be formed on a semiconductor substrate 100, similar to the exemplary method described above in relation to FIGS. 4-6 and 8-11. A mold layer 120′ may then be formed on the semiconductor substrate 100 in which the lower interconnection layer 110 is formed. Any material that can be patterned using a photolithographic process, does not affect the process of forming a via and can be removed can be used for the mold layer 120′. For example, the mold layer 120′ may be formed of an insulating layer.

Next, a mold pattern 120″ may be formed. The process of forming a mold pattern 120″ may be selected according to the material used to form the mold layer 120′ and may be performed using, e.g., a lift-off method.

After the mold layer 120′ is formed, a photoresist layer (not shown) may be coated on the mold layer 120′ and the photoresist layer may be developed/patterned to form a photoresist pattern 125. Subsequently, light may be irradiated onto the mold layer 120′ via the photoresist pattern 125 that defines, e.g., the opening 130. The mold layer 120′ may then be patterned using, e.g., the photoresist pattern 125, as shown in FIG. 12.

Referring to FIG. 13, the mold layer 120′ may be etched using the photoresist pattern 125 as an etching mask. Here, the mold layer 120′ can be etched using, e.g., dry or wet etching according to the material(s) used to form the mold layer 120′. The lower interconnection line 110 may be exposed by etching the mold layer 120′. In such cases, damage of the lower interconnection line 110 can be reduced and/or prevented by using, e.g., an etch selectivity in an etching process and/or by properly stopping the etching process using a time control etch stop method.

Subsequently, the photoresist pattern 125 may be removed. If the lower interconnection line 110 is exposed when the photoresist pattern 125 is removed, the lower interconnection line 110 may be damaged in the process of removing the photoresist pattern 125. Thus, in embodiments of the invention, removal of the photoresist pattern 125 and the patterning of the mold layer 120′ may be simultaneously performed to help prevent and/or reduce damage to the lower interconnection line 110. By removing the photoresist pattern 125 and patterning the mold layer 120′, a mold pattern 120″ that defines the opening 130 may be formed on the semiconductor substrate 100.

Although not shown, subsequent steps of forming a via 131 and a damascene interconnection line 161, e.g., processes corresponding to FIGS. 6, and 8-11 of the exemplary embodiment described above, may be performed in the same manner after forming the mold pattern 120″, as shown in FIG. 13. In exemplary embodiments of the invention, corresponding to FIGS. 12 and 13, the process of removing the mold pattern 120″ may be selected according to the material used to form the mold pattern 120″ and the material used to form the via 131, and the mold pattern 120″ may be removed using, e.g., a lift-off method.

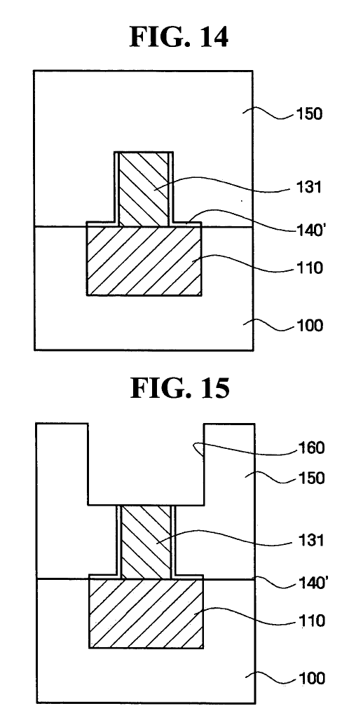

A method of fabricating a damascene interconnection line in a semiconductor device according to another embodiment of the invention will now be described with reference to FIGS. 14 through 16. The method illustrated in FIGS. 14 through 16 relates to a method of selectively forming a diffusion-prevention and etch stop layer in a region in which a lower interconnection line and a remaining via are formed. Only differences between the exemplary embodiment illustrated in FIGS. 12 and 13 and the exemplary embodiment illustrated in FIGS. 4-6 and 8-11 will be described below.

In the exemplary embodiment shown in FIGS. 14-16, a lower interconnection line 110 may be formed in a semiconductor substrate 100 and a via 131 may be formed on the interconnection line, similar to the exemplary method described above in relation to FIGS. 4-6 and 8. In exemplary embodiments corresponding to the structure shown in FIG. 14, after the via 131 is exposed, i.e., corresponding to FIG. 8 of the first exemplary embodiment, a diffusion-prevention and etch stop layer 140′ is selectively formed on exposed portions of the lower interconnection line 110 and the remaining via 131.

As shown in FIG. 14, in embodiments of the invention, the diffusion-prevention and etch stop layer 140′ is not formed on an upper exposed surface of the via 131, i.e., surface of via 131 that is substantially parallel to surface of the semiconductor substrate 100. In embodiments of the invention, the diffusion-prevention and etch stop layer 140′ may only be formed on the via 131 and the lower interconnection line 110 before the trench 160 is formed.

The diffusion-prevention and etch stop layer 140′ may be used to prevent and/or reduce diffusion of the material used to from the lower interconnection line 110 into the ILD layer 150. The diffusion-prevention and etch stop layer 140′ may also reduce and/or prevent the via 131 from being exposed during dry etching during, e.g., formation of the trench 160. Thus, as shown in FIG. 14, the diffusion-prevention and etch stop layer 140′ can be selectively formed only in the region in which the lower interconnection line 11 0 and the remaining via 131 are formed.

The material for forming form the diffusion-prevention and etch stop layer 140′ may be deposited in the selective region using, e.g., electroless plating. For example, CoWP may be used for the diffusion-prevention and etch stop layer 140′, however, in embodiments of the invention, other materials may be used for the diffusion-prevention and etch stop layer.

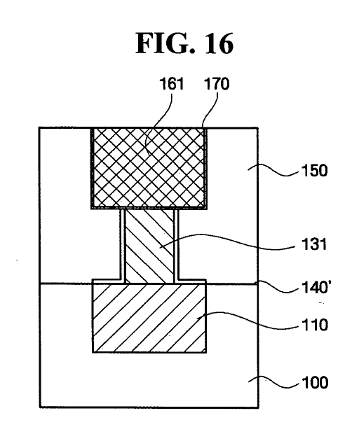

As shown in FIG. 16, subsequent steps of forming a via 131 and a damascene interconnection line 161, e.g., processes corresponding to FIGS. 6, and 8-11 of the exemplary embodiment described above, may be performed in the same manner after forming the trench 160 in the ILD layer 150, as shown in FIG. 15. The diffusion-prevention etch stop layer 140′ only exists at portions above or overlapping with the lower interconnection line 110.

The methods of fabricating a damascene interconnection line in a semiconductor device illustrated in FIGS. 4 through 6 and 8 through 11, FIGS. 12 and 13, and FIGS. 14 through 16 may be combined with one another and can also be changed in various ways using a technology well-known to those skilled in the art.

A semiconductor device according to an exemplary embodiment of the invention will now be described with reference to FIG. 11.

Embodiments of the invention, e.g., the exemplary embodiment of the semiconductor device shown in FIG. 11, may have a structure in which the lower interconnection line 110 and the damascene interconnection line 161 are electrically connected to each other by the via 131. In the embodiment illustrated in FIG. 11, the semiconductor device includes the diffusion-prevention and etch stop layer 140.

The lower interconnection line 110 may be formed on the semiconductor substrate 100. Various materials maybe used to form the lower interconnection line 110 including, e.g., copper, copper alloy, aluminum or aluminum alloy. The lower interconnection line 110 may be formed of, e.g., copper (Cu) for low resistance. The surface of the lower interconnection line 110 may be planarized.

The lower interconnection line 110 may be separated by the upper damascene interconnection line 161 and the ILD layer 150 and may be electrically connected to the damascene interconnection line 161 by the via 131. A conductive material, e.g., Cu, Ni, Sn, W, or alloy thereof, may be filled in the via 131 so that the lower interconnection line 110 and the damascene interconnection line 161 are electrically connected.

The ILD layer 150 may be formed of a material having a high thermal stability and a low dielectric constant. To prevent and/or reduce RC signal delay between the lower interconnection line 110 and a damascene interconnection line 161 to be formed and to suppress interference and an increase in power consumption, the ILD layer 150 may be formed of a material having a low dielectric constant. The ILD layer 150 may have a sufficient thickness to form the via 131 and the trench 160 and may be formed of organic polymer or an inorganic material having a low dielectric constant low-k.

The organic polymer may comprise a low-k dielectric organic polymer, e.g., polyallylether-group resin, ring-shaped fluoride resin, siloxane copolymer, polyallylether-group fluoride resin, polypentafluorostylene, polytetrafluorostylene-group resin, polyimide fluoride resin, polynaphthalene fluoride resin and polycide resin.

The inorganic material may comprise a undoped silicate glass (USG) layer, a tetraethylorthosilicate (TEOS) layer, a fluorine-doped silicate glass (FSG) layer, an organo silicate glass (OSG) layer, a SiOC(SiOC:H) layer, a hydrogensilsesquioxane (HSQ) layer, etc.

The ILD layer 150 may be formed to a thickness of 3000 Å to about 20000 Å. In embodiments of the invention, the ILD layer 150 may have a thickness of about 6000 Å to about 7000 Å. However, the thickness of the ILD layer 150 can be changed in various ways by those skilled in the art.

The ILD layer 150 may be formed on the semiconductor substrate 100 in which the lower interconnection line 110 is formed. The diffusion-prevention and etch stop layer 140 may be interposed between the semiconductor substrate 100, including the lower interconnection line 110, and the via 131 and/or between the via 131 and the ILD layer 150. The diffusion-prevention and etch stop layer 150 may be used to reduce and/or prevent diffusion of the materials used to form the lower interconnection line 110 and the via 131 into the ILD layer 150, the diffusion-prevention and etch stop layer 140 may be interposed between the semiconductor substrate 100 and the ILD layer 150. In embodiments of the invention, the diffusion prevention and etch stop layer 140 may only be provided on or above the lower interconnection line 110 and is in direct contact with at least one of the via 131 and/or the lower interconnection line 110.

The barrier metal layer 170 may be formed between the damascene interconnection line 161, the ILD layer 150 and/or the via 131. The barrier metal layer 170 may be formed of, e.g., Ta, TaN, WN, TaC, TiSiN, and TaSiN. The barrier metal layer 170 may be formed using, e.g., a physical vapor deposition (PVD) technique, a chemical vapor deposition (CVD) technique and an atomic layer deposition (ALD) technique. When copper (Cu) is used as a conductive material, the barrier metal layer 170 may be used to prevent degradation of insulating characteristics of the ILD layer 150 caused by diffusion of Cu. The barrier metal layer 170 may not be formed in embodiments of the invention, according to the type of the conductive material or other characteristics of the semiconductor device.

Hereinafter, a semiconductor device according to another embodiment of the present invention will now be described with reference to FIG. 16. In the semiconductor device of FIG. 16, a diffusion-prevention and etch stop layer 140′ is connected only to a top surface of the lower interconnection line 110 and sidewalls of the via 131. The diffusion-prevention and etch stop layer 140′ can be formed of, e.g., CoWP, which that can be easily selectively-deposited using electroless plating. The other structures of the semiconductor device according to the illustrative embodiment of the invention are substantially the same as those of the semiconductor device shown in FIGS. 4 through 6 and 8 through 11 and a repeated description thereof is omitted.

As described above, in methods of fabricating a damascene interconnection line in a semiconductor device and semiconductor devices fabricated by the same according to one or more aspects of the invention, a filler is not needed such that the number of processing steps may be reduced and the process may be simplified. In addition, pinch-off may be reduced/prevented and a via may be completely filled with a conductive material such that electrical characteristics are maintained and an interconnection line can be reliably formed. In addition, because a process of fabricating a damascene interconnection line and a process of forming a via are separately performed, a damascene interconnection line may be formed of a different material than a material used to form a via. Therefore, stress induced voiding (SIV) and/or electromigration (EM) may be effectively prevented and/or reduced.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of fabricating a damascene interconnection line in a semiconductor device, the method comprising:
forming a lower interconnection line on a semiconductor substrate;
forming a mold pattern that defines an opening through which the lower interconnection line is exposed;
filling the opening with a conductive material to form a via;
removing the mold pattern while maintaining the via on the lower interconnection line;
forming an interlevel dielectric (ILD) layer that covers the lower interconnection line and the via;
patterning the ILD layer, exposing the via, and forming a trench that defines a region in which an interconnection line is to be formed; and
filling the trench to fabricate a damascene interconnection line connected to the via.

2. The method as claimed in claim 1, wherein forming the mold pattern comprises:
forming a photoresist layer on the semiconductor substrate in which the lower interconnection line is formed; and
exposing and developing the photoresist layer.

3. The method as claimed in claim 1, wherein removing the mold pattern comprises removing the mold patter using a stripper including at least one amine-based material.

4. The method as claimed in claim 3, wherein the amine-based material includes at least one of N-methylethanolamine, mono ethanolamine, hydroxylamine and diglycolamine.

5. The method as claimed in claim 1, wherein forming the mold pattern comprises:
forming a mold layer on the semiconductor substrate in which the lower interconnection line is formed;
forming a photoresist pattern, which defines the opening, on the mold layer;
etching the mold layer using the photoresist pattern as an etching mask; and
removing the photoresist pattern.

6. The method as claimed in claim 1, wherein the forming the via comprises selectively filling the opening with the conductive material.

7. The method as claimed in claim 1, wherein forming the via is includes performing electroless plating or chemical vapor deposition (CVD).

8. The method as claimed in claim 1, wherein the conductive material includes at least one of Cu, Ni, Sn, W and alloys thereof.

9. The method as claimed in claim 1, wherein the conductive material is different from a material used to fabricate the damascene interconnection line.

10. The method as claimed in claim 1, further comprising forming a diffusion-prevention and etch stop layer before the forming of the ILD layer, wherein:
forming of ILD layer includes interposing the diffusion-prevention and etch stop layer to cover the lower interconnection line and the via, and
exposing the via includes etching the ILD layer to the diffusion-prevention and etch stop layer that covers the via and removing the diffusion-prevention and etch stop layer that covers the via.

11. The method as claimed in claim 10, wherein the diffusion-prevention and etch stop layer is formed of at least one of SiC, SiN and SiCN.

12. The method as claimed in claim 10, wherein forming the diffusion-prevention and etch stop layer comprises selectively forming the diffusion-prevention and etch stop layer in a region in which the lower interconnection line and the remaining via are formed.

13. The method as claimed in claim 12, wherein the diffusion-prevention and etch stop layer is formed of CoWP.

14. The method as claimed in claim 12, wherein forming the diffusion-prevention and etch stop layer includes performing electroless plating.

15. The method as claimed in claim 1, wherein forming the ILD layer includes forming the ILD layer using spin coating.

16. The method as claimed in claim 1, wherein forming the ILD layer comprises:
conformally depositing an interlevel dielectric (ILD) material; and
planarizing a top surface of the deposited ILD material.

17. A semiconductor device comprising:
a lower interconnection line;
a via formed of conductive material, the via being electrically connected to the lower interconnection line,
a diffusion-prevention and etch stop layer formed on sidewalls of the via; and
a damascene interconnection line electrically connected to the via.

18. The semiconductor device as claimed in claim 17, wherein a barrier metal layer is formed at a boundary between the damascene interconnection line and the via.

19. The semiconductor device as claimed in claim 17, wherein the barrier metal layer is formed of at least one of Ta, TaN, TiN, WN, TaC, WC, TiSiN and TaSiN.

20. The semiconductor device as claimed in claim 17, wherein the conductive material includes at least one of Cu, Ni, Sn, W and alloys thereof.

21. The semiconductor device as claimed in claim 17, wherein the conductive material is different from a material forming the damascene interconnection line.

22. The semiconductor device as claimed in claim 17, wherein the diffusion-prevention and etch stop layer is formed of at least one of SiC, SiN, and SiCN.

23. The semiconductor device as claimed in claim 17, wherein the diffusion-prevention and etch stop layer is formed on the sidewalls of the via that extend away from the lower interconnection line and on a top surface of the lower interconnection line.

24. The semiconductor device as claimed in claim 23, wherein the diffusion-prevention and etch stop layer is formed of CoWP.
